(19) United States
(12) Patent Application Publication
(10) Pub. No.: US 2012/0258565 A1
(43) Pub. Date: Oct. 11, 2012

(54) SUBSTRATE PROCESSING APPARATUS AND METHOD FOR FORMING COATING FILM ON SURFACE OF REACTION TUBE USED FOR THE SUBSTRATE PROCESSING APPARATUS

(75) Inventors: Eisuke NISHITANI, Toyama-city (JP); Yasuo KUNII, Takasaki-city (JP); Kazuyuki TOYODA, Toyama City (JP); Kosaku HIYAMA, Kobe-City (JP); Tomohiro NAKASUJI, Kobe city (JP); Tatsuya HAMAGUCHI, Sendai-city (JP); Kiyoshi MIYAJIMA, Chuo-Ku (JP)

(73) Assignees: TOCALO CO., LTD., Kobe-shi (JP); HITACHI KOKUSAI ELECTRIC INC., Tokyo (JP)

(21) Appl. No.: 13/431,438

(22) Filed: Mar. 27, 2012

(30) Foreign Application Priority Data
Apr. 8, 2011 (JP) 2011-086643

(51) Int. Cl. H01L 31/0236; C23C 16/44

(52) U.S. Cl. 438/71; 118/724; 257/E31.13

(57) ABSTRACT

There is provided a substrate processing apparatus, comprising: a processing chamber in which a plurality of substrates are housed, the substrate having thereon a lamination film composed of any one of copper-indium, copper-gallium, or copper-indium-gallium; a reaction tube formed so as to constitute the processing chamber; a gas supply tube configured to introduce elemental selenium-containing gas or elemental sulfur-containing gas to the processing chamber; an exhaust tube configured to exhaust an atmosphere in the processing chamber; and a heating section provided so as to surround the reaction tube, wherein a porous coating film having a void rate of 5% to 15% mainly composed of a mixture of chromium oxide (CrₓO_{y}:x, y are arbitrary integer of 1 or more) silica is formed on a surface exposed to at least the elemental selenium-containing gas or the elemental sulfur-containing gas, out of the surface of the reaction tube on the processing chamber side.

### TECHNICAL FIELD

The present invention relates to a substrate processing apparatus and a method for manufacturing a solar battery using the substrate processing apparatus, and a method for forming a coating film on a surface of a reaction tube used for the substrate processing apparatus, and particularly relates to the substrate processing apparatus for forming a light absorbing layer of a selenide-based CIS solar battery, and the method for manufacturing the selenide-based CIS solar battery using the same, and the method for forming the coating film of the reaction tube used for the substrate processing apparatus for forming the light absorption layer of the selenide-based CIS solar battery.

### DESCRIPTION OF RELATED ART

The selenide-based CIS solar battery has a structure of sequentially laminating a glass substrate, a metal rear surface electrode layer, a CIS-based light absorbing layer, a high resistance buffer layer, and a window layer. Wherein, the CIS-based light absorbing layer is formed by selenization of a lamination structure of any one of copper (Cu)/gallium (Ga), Cu/indium (In), or Cu—Ga/In. Thus, the selenide-based CIS solar battery has a characteristic that the substrate can be formed thin and also a manufacturing cost can be reduced, because a film with high light absorption coefficient can be formed without using silicon (Si).

Here, patent document 1 can be given as an example of an apparatus that carries out selenization treatment.

A selenization apparatus described in patent document 1 applies selenization treatment to objects by arranging these objects, being a plurality of flat plate-like objects by a holder at constant intervals in parallel to a longitudinal axis of a cylindrical quartz chamber with its surface level vertical to the objects, to thereby selenide the objects by introducing a selenium source.

### Patent Document 1:

Japanese Patent Laid Open Publication No. 2006-186114

### SUMMARY OF THE INVENTION

As described in patent document 1, a quartz chamber (furnace body) is used in a substrate processing apparatus that carries out selenization treatment.

However, the quartz chamber involves a problem that its processing is difficult to thereby increase the manufacturing cost and a long-term delivery period is required. Further, the quartz chamber is easily broken, and therefore is difficult to be handled. Particularly, in the CIS solar battery, its substrate is extremely large (300 mm×1200 mm in patent document 1), and therefore the furnace body itself needs to be large, thus further remarkably showing the aforementioned problem.

Therefore, an object of the present invention is to provide a substrate processing apparatus having a furnace body that can be easily manufactured, compared with a quartz chamber, and further provide a chamber easy to be handled, compared with the quartz chamber.

According to a first aspect of the present invention, there is provided a substrate processing apparatus, comprising:

a processing chamber in which a plurality of substrates are housed, each of the substrates having thereon a lamination film composed of any one of copper-indium, copper-gallium, or copper-indium-gallium;

a reaction tube provided to constitute the processing chamber;

a gas supply tube configured to introduce elemental selenium-containing gas or elemental sulfur-containing gas to the processing chamber;

an exhaust tube configured to exhaust an atmosphere of the processing chamber; and

a heating section provided to surround the reaction tube,

wherein a porous coating film having a void rate of 5% to 15% mainly composed of a mixture of chromium oxide (CrₓO_{y}:x, y are arbitrary integer of 1 or more) silica is formed on a surface exposed to at least the elemental selenium-containing gas or the elemental sulfur-containing gas, out of the surface of the reaction tube on the processing chamber side.

According to other aspect of the present invention, there is provided a method for forming a coating film on a surface of a reaction tube which constitutes a processing chamber for exposing a plurality of substrates having thereon a lamination film composed of any one of copper-indium, copper-gallium, or copper-indium-gallium is formed, to elemental selenium-containing gas or elemental sulfur-containing gas, the method comprising:

degreasing and washing a surface of a base of the reaction tube;

applying blasting and roughening treatment to a surface of the base of the reaction tube;

coating the surface of the roughened base, with slurry of a mixture of chromium oxide (CrₓO_{y}:x, y are arbitrary integer of 1 or more) and silica (SiₓO_{y}:x, y are arbitrary integer of 1 or more);

sintering the base coated with the slurry at a prescribed temperature; and

impregnating chemical refinement agent into the base after sintering,

wherein coating, sintering, and impregnating are repeated prescribed number of times.

A furnace body that can be easily manufactured compared with the quartz chamber can be realized. Further, the furnace body easy to be handled compared with the quartz chamber can be realized.

### BRIEF DESCRIPTION OF THE DRAWINGS

FIG. 1 is a side cross-sectional view of a processing furnace according to a first embodiment of the present invention.

FIG. 2 is a cross-sectional view of the processing furnace viewed from a left direction on a paper face of FIG. 1.

FIG. 3 is a view describing a coating film according to the first embodiment of the present invention.

FIG. 4 is a view describing an effect due to a difference of deviation of the coefficient of linear expansion between the coating film and a base of a processing furnace of the present invention.

FIG. 5 is a side cross-sectional view of a processing furnace according to a second embodiment of the present invention.

### DETAILED DESCRIPTION OF THE INVENTION

### First Embodiment

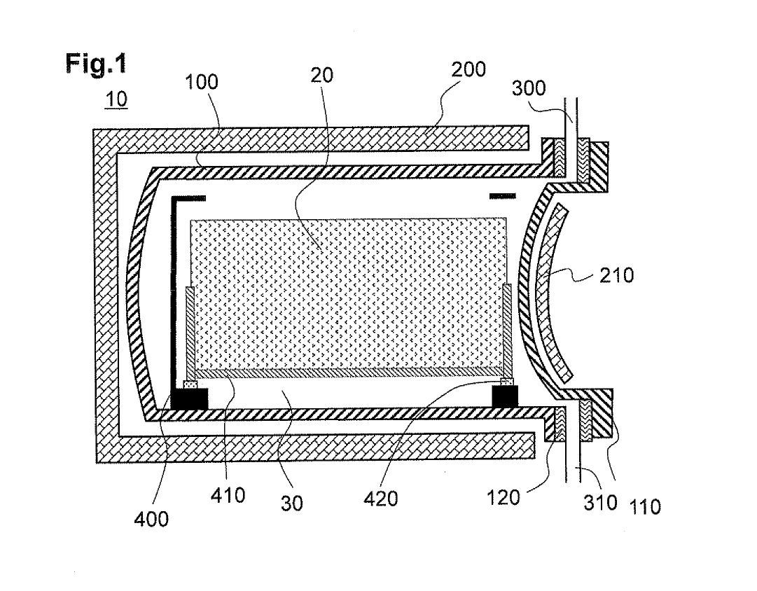

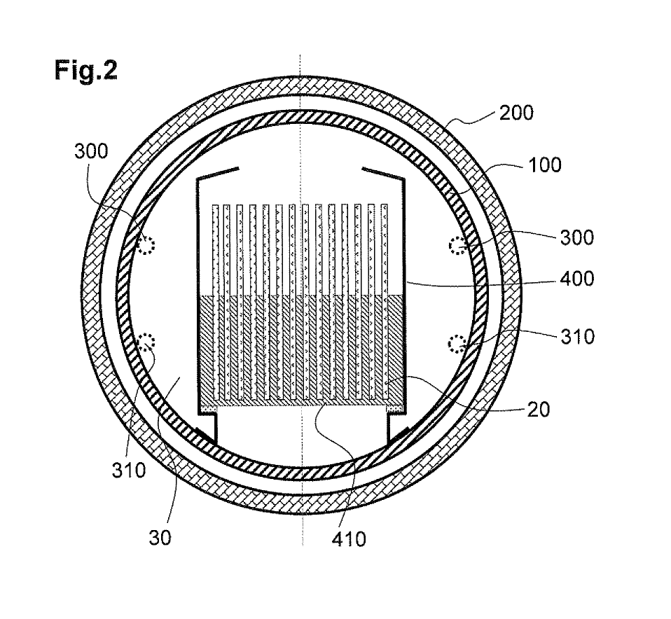

Embodiments of the present invention will be described next, with reference to the drawings. FIG. 1 is a side cross-sectional view of a processing furnace assembled into a substrate processing apparatus that performs selenization treatment according to the present invention. Further, FIG. 2 is a cross-sectional view of the processing furnace viewed from a left side on the paper face of FIG. 1.

The processing furnace 10 has a reaction tube 100, being a furnace body, made of a metal material such as stainless. The reaction tube 100 has a hollow cylindrical shape, with its one end closed and the other end opened. A processing chamber 30 is formed by the hollow portion of the reaction tube 100. A cylindrical shaped manifold 120 with its both ends opened, is provided concentrically with the reaction tube 100, on the opening part side of the reaction tube 100. An O-ring (not shown), being a seal member, is provided between the reaction tube 100 and the manifold 120.

A movable seal cap 110 is provided in the opening part where the reaction tube 100 of the manifold 120 can't be provided. The seal cap 110 is made of a metal material such as stainless, and has a projection shape so as to be partially inserted into the opening part of the manifold 120. The O-ring, being the seal member, (not shown) is provided between the movable seal cap 110 and the manifold 120, and when the processing is performed, the seal cap 110 air-tightly closes the opening part side of the reaction tube 100.

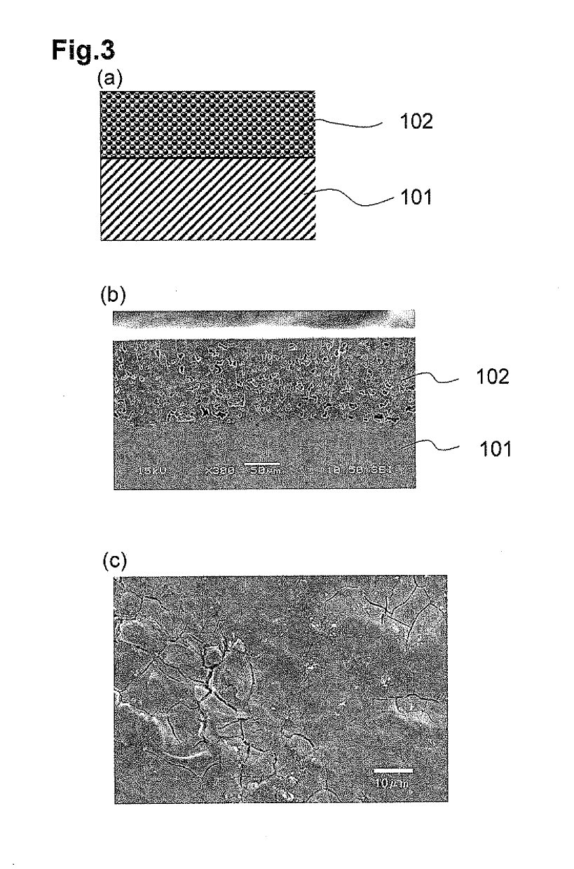

An inner wall 400 is provided inside the reaction tube 100, for placing a cassette 410 which holds a plurality of glass substrates (for example 30 to 40 glass substrates) with a laminated film formed thereon composed of copper (Cu), indium (In), and gallium (Ga). As shown in FIG. 3, the inner wall 400 is formed so that one end thereof is fixed to an inner circumferential surface of the reaction tube 100, and the cassette 410 is placed in the center of the reaction tube 100 via an installation base 420. The inner wall 400 is formed so that a pair of members provided in such a manner as interposing the cassette 410 between them, are connected to each other at both ends, thus increasing the strength thereof. As shown in FIG. 1, the cassette 410 has holding members capable of holding a plurality of glass substrates 20 in an upright state arranged in a horizontal direction, at both ends of the glass substrates 20. Further, the holding members at both ends are fixed by a pair of fixing bars provided on the lower side of the holding member, and lower ends of the plurality of glass substrates are exposed to the inside of the reaction chamber. Note that the fixing bar for fixing the both ends of the cassette 410 may be provided on the upstream side of the holding members at both ends to increase the strength of the cassette 410.

Further, a furnace heating section 200 having a hollow cylindrical shape is provided, with one end closed and the other end opened to surround the reaction tube 100. Further, a cap heating section 210 is provided on a side face opposite to the reaction tube 100 of the seal cap 110. Inside of the processing chamber 30 is heated by the furnace heating section 200 and the cap heating section 210. Note that the furnace heating section 200 is fixed to the reaction tube 100 by a fixing member not shown, and the cap heating section 210 is fixed to the seal cap 110 by the fixing member not shown. Further, a cooling unit such as a water cooling unit not shown is provided in the seal cap 110 and the manifold 120, for protecting the O-ring having low heat resistance.

A gas supply tube 300 is provided in the manifold 120, for supplying selenium hydride (“H₂ Se” hereafter), being elemental selenium-containing gas (selenium source). H₂ Se supplied from the gas supply tube 300 is supplied to the processing chamber 30 via a space between the manifold 120 and the seal cap 110. Further, an exhaust tube 310 is provided at a different position from the gas supply tube 300 of the manifold 120. The atmosphere in the processing chamber 30 is exhausted from the exhaust tube 310 via the space between the manifold 120 and the seal cap 110. Note that if a cooling spot is cooled to 150° C. or less by the aforementioned cooling unit, unreacted selenium is condensed at this spot, and therefore temperature may be controlled from about 150° C. to 170° C.

The reaction tube 100 is made of the metal material such as stainless. The metal material such as stainless is easy to be processed, compared with quartz. Therefore, a large-sized reaction tube 100 used for the substrate processing apparatus that applies selenization treatment to the CIS solar battery, can be easily manufactured. The number of the glass substrates that can be housed in the reaction tube 100 can be increased, and therefore the manufacturing cost of the CIS solar battery can be reduced.

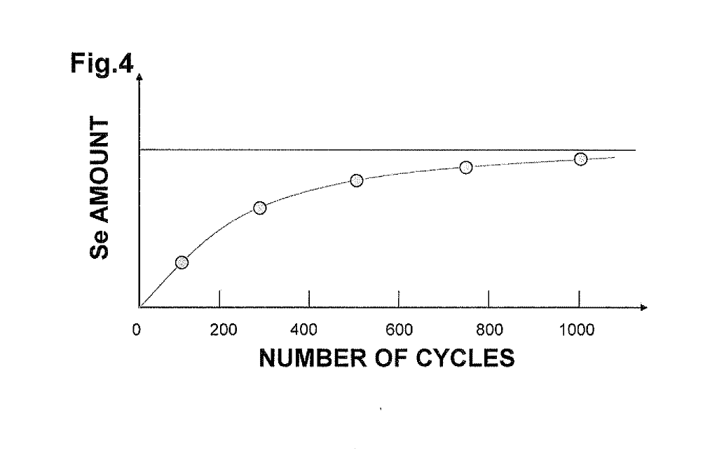

Further, in this embodiment, as shown in FIG. 3, at least the surface of the reaction tube 100 exposed to the atmosphere in the processing chamber 30, is coated with a coating film formed on the metal material such as stainless, being a base 101, as shown in FIG. 4, with high selenization resistance compared with the metal material such as stainless. A generally used metal material such as stainless has extremely high reactivity and accelerates corrosion by heating the gas such as H₂ Se at 200° C. or more. However, by forming the coating film with high selenization resistance like this embodiment, the corrosion by the gas such as H₂ Se can be suppressed, and therefore the generally used metal material such as stainless can be used. Thus, the manufacturing cost of the substrate processing apparatus can be reduced. Note that the coating film mainly composed of ceramic is preferable as the coating film with high selenization resistance.

Next, an experiment for selenization resistance was conducted by forming four kinds of films on stainless which is the base of the reaction tube 100, such as (1) a silica (SiO₂) film of 1 to 2 μm, (2) a chromium oxide (Cr₂O₃) film of 1 to 2 μm, (3) Cr₂O₃+SiO₂ film of 70 μm, and (4) Al₂O₃+SiO₂ films of 100 μm by melt-spraying alumina (Al₂O₃) and thereafter applying sealing treatment thereto by SiO₂, and the films were exposed to a selenization atmosphere of H₂ Se (4%) and Ar (96%). Note that the temperature was set to 650 degrees, and the time per one exposure to selenization atmosphere was set to 1 hour. Results thereof were shown in table 1.

TABLE 1

| | Sample | | | |
|---|---|---|---|---|
| | | | Cr₂O₃ + | Al₂O₃ + |
| | SiO₂ | Cr₂O₃ | SiO₂ | SiO₂ |
| Film thickness | 1~2 μm | 1~2 μm | 70 μm | 100 μm |
| Result | NG | NG | Good | NG |
| | | | (10 number of times) | |

First, Cr₂O₃ film of (2) and Al₂O₃+SiO₂ film of (4) were peeled-off only by one exposure to the selenization atmosphere. Although SiO₂ film of (1) was not peeled-off only by one exposure, discoloration occurs on the surface after repeating 10 exposures, thus causing a partial peel-off to occur. Meanwhile, Cr₂O₃+SiO₂ film of (3) was not peeled-off even if repeating exposures.

It can be considered that the above-described result is influenced by the porous state of the Cr₂O₃+SiO₂ film as shown in FIG. 3B. Note that FIG. 3B is a cross-sectional SEM photograph of a member with stainless coated with coating Cr₂O₃+SiO₂ film, being the base 101 of the reaction tube. Thus, by setting the coating film in a porous state, thermal expansion/contraction can be flexibly coped with, which is caused by a difference of coefficient of linear expansion between the base 101 formed by the metal material such as stainless and the coating film 102, thus not allowing the Cr₂O₃+SiO₂ film to be peeled-off. Wherein, the coating film 102 is preferably a porous film having a void rate of 5% to 15%. With the void rate of 5% or less, it is difficult to flexibly follow the thermal expansion/contraction, and meanwhile with the void rate of 15% or more, there is a risk that a selenium source reaches the stainless material, being the base material. Note that the void rate can be calculated by estimating an area of a portion, being a void, in the cross-sectional SEM photograph of the coating film as shown in FIG. 3B.

Meanwhile, it can be considered that SiO₂ film of (1) and Cr₂O₃ film of (2) are extremely dense films and therefore can't follow the thermal expansion of the base 101, being the metal material such as stainless, thus causing the peel-off of the films by stress. Further, it can be considered that Al₂O₃+SiO₂ film of (4) has insufficient environmental shielding performance, thus allowing the selenium source to reach a boundary interface of the base 10 through inside of the coating film 102, to thereby generate corrosion on the surface of the base 101, resulting in the peel-off.

FIG. 3C is the SEM photograph of the surface of Cr₂O₃+SiO₂ film after the above-described test was conducted.

From FIG. 3C, although it is found that microscopic cracks of several μm to scores of μm are generated due to repeated heat treatment. However, it is also found that there is completely no sign of peel-off in outer appearance, and Cr₂O₃+SiO₂ film sufficiently functions as the coating film.

Further, in order to examine a life span of the selenization resistance of the coating film, Se amount was evaluated at the time of accumulating on the interface and in the coating film, or at the time of being changed from an oxide film to a selenide film, when selenization treatment was repeated. FIG. 4 is a view showing a comparison of the number of cycles of the selenization treatment, and the Se amount at the time of accumulating on the interface and in the coating film, or at the time of being changed from the oxide film to the selenide film.

As is described from FIG. 3C, there was completely no sign of peel-off of the coating film, although microscopic cracks were generated even in a case of the coating film formed on SUS304. In FIG. 4 as well, there was completely no sign of peel-off, although the selenization treatment of 1000 number of times was conducted at 450°. Se on the interface shows a saturation tendency, and a degree of increase is estimated to be small even if the selenization treatment of the number of times more than 1000 is carried out. If annual rate of operation is taken into consideration, the result of 1000 number of times of selenization treatment in FIG. 4 corresponds to the result in a case of carrying out selenization treatment for about 1 year in mass production. Although the selenization treatment of 1000 number of times at most can be verified here, no fluctuation can be observed in a coating state even if the number of times of treatment is increased more than 1000 number of times. Therefore, it can be estimated that there is a life span of two or more times of the 1000 number of times in principle.

As described above, when the metal material such as stainless is used as the base material of the reaction tube, for increasing a size of the processing furnace of a selenization treatment apparatus, the life span of the processing furnace can be prolonged by forming on the surface of the reaction tube, the porous coating film having the void rate of 5% to 15%, mainly composed of a mixture of silica and chromium oxide. Note that in the above explanation, silica is described as SiO₂, and chromium oxide is described as Cr₂O₃. However, silica may be SiₓO_{y} (x and y are arbitrary integers of 1 or more), and chromium oxide may be CrₓO_{y} (x and y are arbitrary integers of 1 or more).

Further, the aforementioned coating film may also be formed on a part of the seal cap 110, the manifold 120, the gas supply tube 300, and the exhaust tube 310 respectively, which is exposed to the selenium source. However, coating may not be applied to a part cooled to 200° C. or less by the cooling unit for protecting the O-ring, etc., because the reaction is not caused even if the metal material such as stainless is brought into contact with the selenium source.

Next, the method for forming the porous Cr₂O₃+SiO₂ film, being the coating film, will be described.

First, degreasing/washing were performed to the surface of the base material for removing stains, etc., on the surface of the metal material such as stainless, being the base 101 of the reaction tube 100, and thereafter blasting is applied to the surface of the base 101, to thereby roughen the surface of the base 101. Thereafter, the surface is coated with slurry of a mixture mainly composed of silica (SiₓO_{y}) and chromium oxide (CrₓO_{y}) (coating step), which is then sintered at 500° C. to 650° C. (sintering step). Further, the chemical refinement agent is impregnated into the microscopic cracks generated in the sintering step (impregnating step). These coating step, sintering step, and impregnating step are repeated to thereby form the coating film.

Thus, by repeating the coating step, the sintering step, and the impregnating step, FeCr-based oxide layer can be formed in the vicinity of the interface (boundary) between the stainless base material and the coating film. This oxide layer has an effect of suppressing the corrosion of the boundary interface of the base material, and further suppressing the corrosion of the stainless base material due to the selenium source.

Next, explanation will be given for the method for manufacturing the substrate, being a part of the method for manufacturing the CIS solar battery, which is performed using the processing furnace of this embodiment.

First, 30 to 40 glass substrates with a laminated film formed thereon composed of copper (Cu), indium (In), and gallium (Ga), are prepared in the cassette 410, and the cassette 410 is loaded into the processing chamber in a state that a movable seal cap 110 is removed from the manifold 120 (loading step). Loading of the cassette 410 is performed, for example, in such a way that a lower part of the cassette 410 is supported by the arm of a loading/unloading device not shown, and in a lifting state, the cassette 410 is moved into the processing chamber 30, and after the cassette 410 reaches a prescribed position, the arm is moved below, to thereby place the cassette 410 on an installation base 420.

Thereafter, inside of the processing chamber 30 is replaced with inert gas such as nitrogen gas (replacement step). After the atmosphere in the processing chamber is replaced with the inert gas, in a normal temperature state, the selenium source such as H₂ Se gas diluted to 1 to 20% (preferably 2 to 20%) by the inert gas, is introduced from the gas supply tube 300. Next, the temperature is increased at a rate of 3 to 50° C. per minute, up to 400 to 550° C. and preferably 450° C. to 550° C. in a state that the selenium source is sealed, or in a state that a constant amount of the selenium source is flowed by exhausting the constant amount of the selenium source from the exhaust tube 310. After the temperature is increased to a prescribed temperature, this state is maintained for 10 to 180 minutes, preferably for 20 to 120 minutes, to thereby carry out selenization treatment so that a light absorbing layer of the CIS solar battery is formed (formation step).

Thereafter, the inert gas is introduced from the gas supply tube 300, then the atmosphere in the processing chamber 30 is replaced, and the temperature is decreased to a prescribed temperature (temperature decreasing step). After the temperature is decreased to the prescribed temperature, the processing chamber 30 is opened by moving the seal cap 110, and the cassette 410 is unloaded by the arm of a loading/unloading device not shown (unloading step), to thereby end a series of processing.

### Second Embodiment

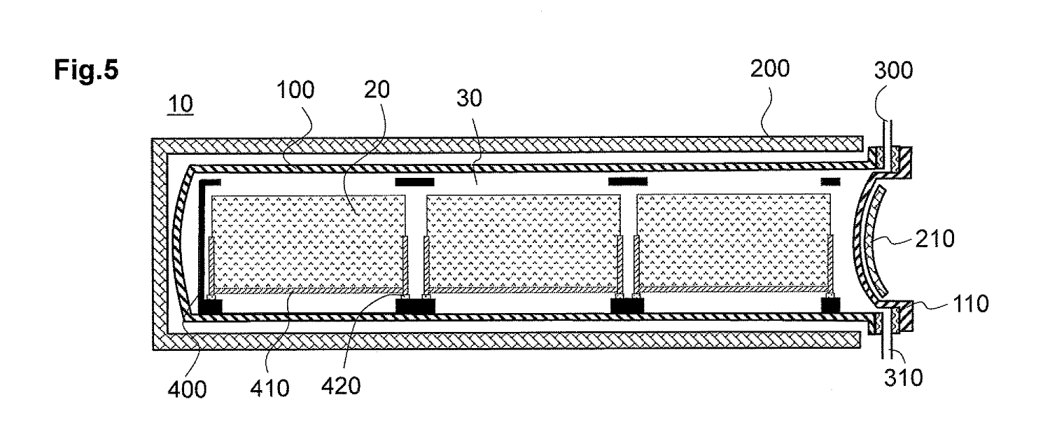

Other embodiment of the processing furnace 10 shown in FIG. 1 and FIG. 2 will be described using FIG. 5. In FIG. 5, the same signs and numerals are assigned to a member having the same functions as the functions of FIG. 1 and FIG. 2. Further, here, different points from the first embodiment will be mainly described.

In a second embodiment shown in FIG. 5, a different point is that a plurality of cassettes 410 (three in this embodiment) are arranged in a direction parallel to the surface of a plurality of glass substrates, unlike the first embodiment wherein only one cassette 410 that holds the plurality of glass substrates 20 is placed.

In the present invention, not a conventional quartz reaction tube, but the metal material such as stainless, is used as the base of the reaction tube 100. Accordingly, even if the size of the reaction tube 100 is increased, molding of the reaction tube is facilitated compared with the quartz reaction tube, and the increase of the cost is small compared with the cost of the quartz reaction tube. Therefore, the number of glass substrates 20 that can be processed at once, can be increased, and the manufacturing cost of the CIS solar battery can be reduced.

Further, by using the metal material such as stainless as the base of the reaction tube, the reaction tube is easy to be handled compared with the quartz reaction tube, and the size of the reaction tube can be increased.

In the present invention according to the first embodiment and the second embodiment, at least one of the following effects can be realized.

(1) The porous coating film 102 with 5% to 15% of void rate mainly composed of chromium oxide and SiO₂ is formed on the base 101 of the reaction tube 100. Therefore, the reaction tube 100 with excellent selenization resistance can be formed, and also it can be formed by the metal material. Accordingly, a large reaction tube 100 can be realized.
(2) In the aforementioned (1), a plurality of cassettes 410 holding a plurality of glass substrates 20 are arranged side by side in the direction parallel to the surface of the glass substrates 20. Therefore, the number of the glass substrates that can be processed at once, can be increased, and the manufacturing cost of the CIS solar battery can be reduced.

As described above, embodiments of the present invention have been described using the drawings. However, the embodiments can be variously modified in a range not departing from the gist of the present invention. For example, in the aforementioned embodiment, explanation has been given for the selenization treatment applied to a plurality of glass substrates composed of copper (Cu), indium (In), and gallium (Ga). However, the present invention is not limited thereto, and the selenization treatment may also be applied to a plurality of glass substrates composed of copper (Cu)/indium (In) and copper (Cu)/gallium (Ga). Further, this embodiment refers to the selenization treatment which is high in reactivity with the metal material. However, in a case of the CIS solar battery, instead of the selenization treatment, or after the selenization treatment, elemental sulfur-containing gas is supplied to carry out sulfurization treatment in some cases. At this time as well, the number of glass substrates capable of carrying out sulfurization treatment at once, can be increased by using a large-sized reaction furnace of this embodiment, and therefore reduction of the manufacturing cost can be realized.

Preferred main aspects of the present invention will be supplementary described finally.

(1) There is provided a substrate processing apparatus, comprising:

a processing chamber in which a plurality of substrates are housed, each of the substrates having thereon a lamination film composed of any one of copper-indium, copper-gallium, or copper-indium-gallium;

a reaction tube provided to constitute the processing chamber;

a gas supply tube configured to introduce elemental selenium-containing gas or elemental sulfur-containing gas to the processing chamber;

an exhaust tube configured to exhaust an atmosphere of the processing chamber; and

a heating section provided to surround the reaction tube,

wherein a porous coating film having a void rate of 5% to 15% mainly composed of a mixture of chromium oxide (CrₓO_{y}:x, y are arbitrary integer of 1 or more) silica is formed on a surface exposed to at least the elemental selenium-containing gas or the elemental sulfur-containing gas, out of the surface of the reaction tube on the processing chamber side.

(2) There is provided the substrate processing apparatus according to the aforementioned (1), wherein a metal material of a base of the reaction tube is stainless.
(3) There is provided the substrate processing apparatus according to the aforementioned (2), wherein the coating film has a FeCr-based oxide layer in the vicinity of a boundary between the coating film and the base of the reaction tube.
(4) There is provided the substrate processing apparatus according to any one of the aforementioned (1) to (3), wherein a plurality of cassettes are arranged in a direction parallel to surfaces of the plurality of substrates.
(5) There is provided a method for forming a coating film on a surface of the reaction tube which constitutes a processing chamber for exposing a plurality of substrates having thereon a lamination film composed of any one of copper-indium, copper-gallium, or copper-indium-gallium is formed, to elemental selenium-containing gas or elemental sulfur-containing gas, the method comprising:

degreasing and washing a surface of a base of the reaction tube;

applying blasting and roughening treatment to a surface of the base of the reaction tube;

coating the surface of the roughened base, with slurry of a mixture of chromium oxide (CrₓO_{y}:x, y are arbitrary integer of 1 or more) and silica (SiₓO_{y}:x, y are arbitrary integer of 1 or more);

sintering the base coated with the slurry at a prescribed temperature; and

impregnating chemical refinement agent into the base after sintering,

wherein the steps of coating, sintering, and impregnating are repeated prescribed number of times.

What is claimed is:

1. A substrate processing apparatus, comprising:
a processing chamber in which a plurality of substrates are housed, each of the substrates having thereon a lamination film composed of any one of copper-indium, copper-gallium, or copper-indium-gallium;
a reaction tube provided to constitute the processing chamber;
a gas supply tube configured to introduce elemental selenium-containing gas or elemental sulfur-containing gas to the processing chamber;
an exhaust tube configured to exhaust an atmosphere in the processing chamber; and
a heating section provided to surround the reaction tube,
wherein a porous coating film having a void rate of 5% to 15% mainly composed of a mixture of chromium oxide (CrₓO_{y}:x, y are arbitrary integer of 1 or more) silica is formed on a surface exposed to at least the elemental selenium-containing gas or the elemental sulfur-containing gas, out of the surface of the reaction tube on the processing chamber side.

2. The substrate processing apparatus according to claim 1, wherein a metal material of a base of the reaction tube is stainless.

3. The substrate processing apparatus according to claim 2, wherein the coating film has a FeCr-based oxide layer in the vicinity of a boundary between the coating film and the base of the reaction tube.

4. The substrate processing apparatus according to any one of claim 1, wherein a plurality of cassettes are arranged in a direction parallel to surfaces of the plurality of substrates.

5. A method for forming a coating film on a surface of the reaction tube which constitutes a processing chamber for exposing a plurality of substrates having thereon a lamination film composed of any one of copper-indium, copper-gallium, or copper-indium-gallium is formed, to elemental selenium-containing gas or elemental sulfur-containing gas, the method comprising:
degreasing and washing a surface of a base of the reaction tube;
applying blasting and roughening treatment to a surface of the base of the reaction tube;
coating the surface of the roughened base, with slurry of a mixture of chromium oxide (CrₓO_{y}:x, y are arbitrary integer of 1 or more) and silica (SiₓO_{y}:x, y are arbitrary integer of 1 or more);
sintering the base coated with the slurry at a prescribed temperature; and
impregnating chemical refinement agent into the base after sintering,
wherein the steps of coating, sintering, and impregnating are repeated prescribed number of times.
